(19) United States
(12) Patent Application Publication
(10) Pub. No.: US 2026/0156767 A1
(43) Pub. Date: Jun. 4, 2026

(54) DISPLAY DEVICE

(71) Applicant: LG Display Co., Ltd., Seoul (KR)

(72) Inventor: Junil Kwon, Gumi-si (KR)

(73) Assignee: LG Display Co., Ltd., Seoul (KR)

(21) Appl. No.: 19/346,095

(22) Filed: Sep. 30, 2025

(30) Foreign Application Priority Data
Nov. 29, 2024 (KR) 10-2024-0175082

(51) Int. Cl. H05K 5/03; H05K 5/02

(52) U.S. Cl. CPC H05K 5/03; H05K 5/0247

(57) ABSTRACT

The present disclosure relates to a display device. A display device may include a display panel, a metal plate disposed at the rear of the display panel, a first circuit board disposed at the rear of the metal plate, a second circuit board disposed at the rear of the metal plate and above the first circuit board, a third circuit board disposed at the rear of the metal plate and electrically connecting the first circuit board and the second circuit board, a first connector electrically connecting the first circuit board and the third circuit board, and a guard member coupled to the first circuit board and the third circuit board, with a portion disposed above a separation space formed between the first circuit board and the third circuit board.

### CROSS REFERENCE TO RELATED APPLICATION

This application claims priority to and benefit of Korean Patent Application No. 10-2024-0175082, filed on Nov. 29, 2024, which is hereby incorporated by reference as if fully set forth herein.

### TECHNICAL FIELD

The present disclosure relates to a display device and more particularly to, for example, without limitation, a display device having a structure with improved durability.

### DESCRIPTION OF THE RELATED ART

The content described in this section merely provides background information on the disclosure and does not constitute prior art.

As society enters the full-fledged information age, the field of display devices that visually represent electrical information signals has rapidly advanced, and research is ongoing to improve performance aspects such as reduced thickness, lighter weight, and lower power consumption for various types of display devices.

Examples of such display devices may include Liquid Crystal Display (LCD) devices, Quantum Dot Display (QD) devices, Field Emission Display (FED) devices, Electro-Wetting Display (EWD) devices, and Organic Light Emitting Display (OLED) devices.

Display devices have been miniaturized to enhance portability for users or to be installed in mobile equipment such as vehicles, thereby improving user convenience.

Furthermore, display devices have been continuously improved to increase screen resolution and brightness, providing clearer images to users.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

A display device may include a circuit board for operating the display device. The circuit board may be provided with a power supply device for supplying electric power to the display device and a control unit for controlling the operation of the display device.

The circuit board may include various active elements, passive elements, circuits, and connectors for electrical connection to implement the control unit.

A plurality of circuit boards may be provided in the display device to realize the power supply and the control unit. The plurality of circuit boards may be electrically connected through connectors.

Since connectors occupy a certain volume, a gap may be formed between a circuit board and a connector when electrically connecting one circuit board to another.

Foreign substances such as dust may enter this gap. If foreign substances accumulate in the gap between the circuit board and the connector, they may cause disconnection or other electrical failures in the electrical connection structure.

In particular, when the display device is continuously used, foreign substances may continuously enter such gaps, potentially causing malfunction or failure of the display device, and in severe cases, combustible foreign substances may even cause a fire in the display device.

Depending on the arrangement structure of the circuit boards, such gaps may be formed in a direction parallel to the direction of gravity.

External foreign substances may fall due to gravity and may easily enter gaps formed in a direction parallel to gravity. Foreign substances that continuously enter and accumulate in the gaps may adversely affect the display device as described above.

Therefore, there is a need to develop a display device having a structure capable of blocking foreign substances such as dust from entering the gap formed at the connection portion between circuit boards.

Accordingly, it is an object of the present disclosure to provide a display device including a structure having a guard member capable of suppressing the ingress of foreign substances into the gap formed at the connection portion between the circuit boards.

It is another object of the present disclosure to provide a display device including a structure having a guard member capable of suppressing the ingress of foreign substances such as dust, which fall due to gravity, into such a gap.

The objects of the present disclosure are not limited to those mentioned above, and other objects and advantages not explicitly stated will be understood from the following description and will become more apparent through example embodiments of the present disclosure. Moreover, it will be readily apparent that the objects and advantages of this specification can be realized by the means and combinations thereof set forth in the claims.

According to an example embodiment, a display device may include a display panel, a metal plate disposed at the rear of the display panel, a first circuit board disposed at the rear of the metal plate, a second circuit board disposed at the rear of the metal plate and above the first circuit board, a third circuit board disposed at the rear of the metal plate and electrically connecting the first circuit board and the second circuit board, a first connector electrically connecting the first circuit board and the third circuit board, and a guard member coupled to the first circuit board and the third circuit board, with a portion disposed above a separation space formed between the first circuit board and the third circuit board.

The guard member may have one end adhered to one surface of the third circuit board and another end adhered to one surface of the first circuit board.

The guard member may be disposed to cover the separation space formed between the first circuit board and the third circuit board from above, thereby suppressing the entry of foreign substances descending due to gravity into the separation space.

According to another example embodiment, a display device may include a metal plate, a first circuit board disposed at the rear of the metal plate, a second circuit board disposed at the rear of the metal plate and above the first circuit board, a third circuit board disposed at the rear of the metal plate and electrically connecting the first circuit board and the second circuit board, a first connector electrically connecting the first circuit board and the third circuit board, and a guard member coupled to the first circuit board and the third circuit board and disposed to cover a separation space formed between the first circuit board and the third circuit board from above.

According to another example embodiment, a display device may include a display panel disposed in front of the metal plate, a polarizer disposed in front of the display panel, a cover window disposed in front of the polarizer, and a back plate disposed at the rear of the display panel and in front of the metal plate.

In the display device according to example embodiments of the present disclosure, the guard member may be coupled to the first circuit board and the third circuit board, with a portion disposed above a separation space formed between the first circuit board and the third circuit board.

The guard member may be placed above a separation space having an open upper side and a closed lower side. This structure effectively blocks foreign substances, such as dust, descending due to gravity from the upper portion of the display device from entering the separation space.

Thus, the guard member may suppress the entry of foreign substances into the separation space, thereby effectively reducing or preventing malfunction or failure of the display device caused by accumulation of foreign substances in the separation space, and improving the durability of the display device.

Additionally, in the display device according to example embodiments of the present disclosure, the guard member may be fabricated in a flat state and easily bent during the assembly process of the display device to be mounted to the display device. This structure effectively suppresses the entry of foreign substances into the separation space without introducing complex structures or processes. Thus, the display device can be significantly improved while reducing manufacturing costs.

Furthermore, in the display device according to example embodiments of the present disclosure, the use of the guard member may suppress the entry of foreign substances into the interior of the device, thereby reducing or preventing malfunctions or increased power consumption caused by foreign substances, and enabling the realization of a low-power display device.

In addition to the aforementioned effects, other advantageous effects of the present disclosure will be provided along with the detailed description of the disclosure.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by one or more the following claims. Nothing in this section should be taken as a limitation on those claims. Further aspects and advantages are discussed below in conjunction with example embodiments of the disclosure.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain principles of the disclosure. In the drawings:

FIG. 1 is a perspective view of a display device according to an example embodiment;

FIG. 2 is a front view of a display device according to an example embodiment;

FIG. 3 is a rear view of a display device according to an example embodiment;

FIG. 4 is an exploded perspective view of a display device according to an example embodiment;

FIG. 5 is a partial side view of a display device according to an example embodiment;

FIG. 6 is an enlarged view of a portion of FIG. 5;

FIG. 7 is a view illustrating a third circuit board and a guard member according to an example embodiment; and

FIG. 8 is a perspective view illustrating the guard member in a bent state from FIG. 7.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, where a detailed description of well-known functions or configurations related to this document may unnecessarily obscure a feature or aspect of the present disclosure, the detailed description thereof may be omitted or may be briefly provided. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout unless otherwise specified. Names of the respective elements used in the following explanations may be selected only for convenience of writing the specification and may be thus different from those used in actual products.

The aforementioned objectives, features, and advantages of the present disclosure will be described in detail with reference to the accompanying drawings, enabling those skilled in the art to easily implement the technical idea of the disclosure. Hereinafter, example embodiments of the present disclosure will be described in detail with reference to the accompanying drawings.

Although terms such as ‘first,’ ‘second,’ and the like may be used to describe various components, these components are not limited by these terms. These terms are merely used to refer to one component separately from another, and unless explicitly stated otherwise, the first component may be the second component, and vice versa.

Throughout the specification, unless explicitly stated otherwise, each component may be singular or plural. Throughout the drawings and the detailed description, unless otherwise described, the same drawing reference numerals should be understood to refer to the same elements, features, and structures. The relative size and depiction of these elements may be exaggerated for clarity, illustration, and convenience.

The singular expressions used in this specification include the plural expression, and vice versa, unless the context clearly indicates otherwise. In this application, terms such as ‘comprising’ or ‘including’ should not be interpreted as necessarily including all the components or steps listed in the specification; some components or steps may be excluded, or additional components or steps may be included.

Throughout the specification, the term ‘A and/or B’ means A, B, or both A and B, unless otherwise stated, and the term ‘C to D’ means C or more and D or less, unless otherwise stated.

Any implementation described herein as an “example” is not necessarily to be construed as preferred or advantageous over other implementations.

In addition, where any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even where a relevant description is not specified. Further, the term “may” fully encompasses all the meanings of the term “can”.

In the description of the various example embodiments of the present disclosure, where positional relationships are described, for example, where a position relation between two parts is described as, for example, “on,” “over,” “under,” and “next,” or the like, one or more other parts may be located between the two parts unless a more limiting term, such as “just” or “direct(ly),” is used. For example, where an element or layer is disposed “on” another element or layer, a third element or layer may be interposed therebetween.

In the description of a temporal relationship, where the temporal order is described as, for example, “after,” “subsequent,” “next,” and “before,” a case that is not continuous may be included unless a more limiting term, such as “just,” “immediate(ly),” or “direct(ly),” is used.

Also, where an element or layer is described as being “connected,” “coupled,” or “adhered” to another element or layer, the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements may be so disposed to directly contact each other, or may be so disposed without directly contacting each other.

It will be apparent to those skilled in the art that various modifications and variations can be made to the embodiments of the present disclosure without departing from the technical idea or scope of the present disclosure. Thus, it is intended that the present disclosure covers the modifications and variations of this disclosure provided they come within the scope of the appended claims and their equivalents.

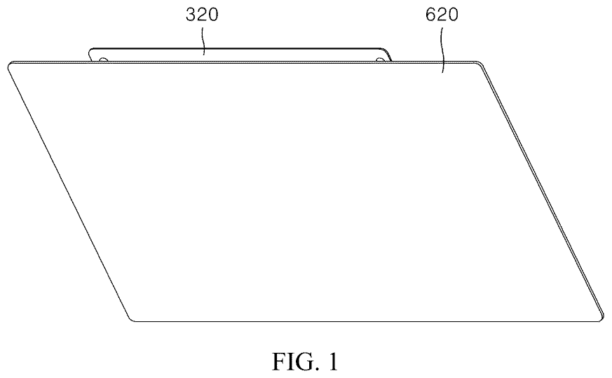

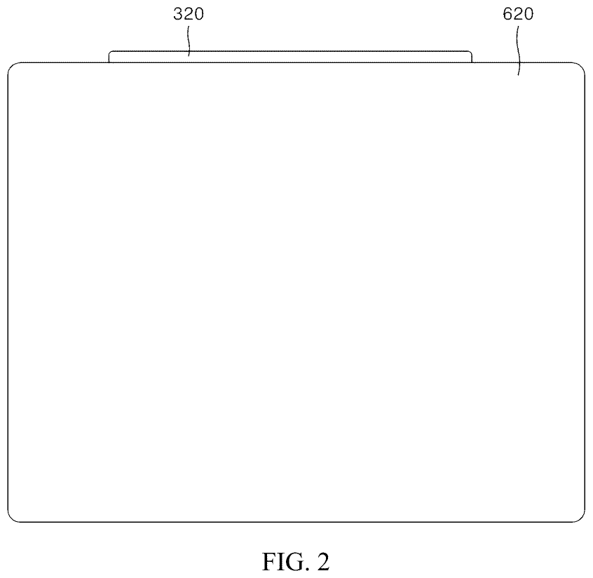

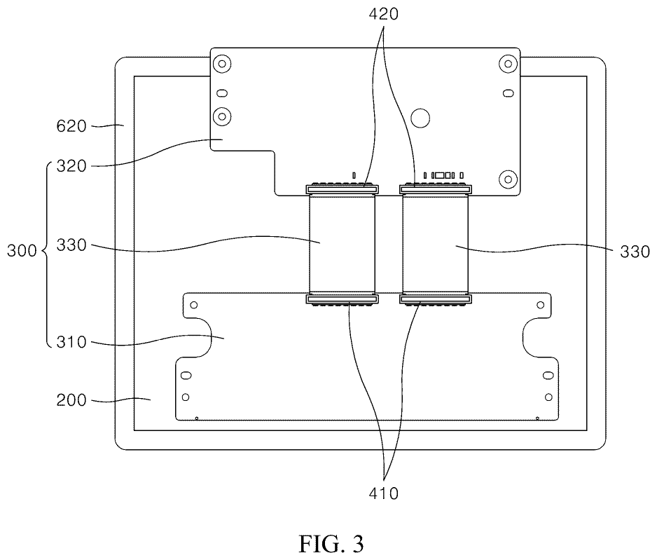

FIG. 1 is a perspective view of a display device according to an example embodiment. FIG. 2 is a front view of a display device according to an example embodiment. FIG. 3 is a rear view of a display device according to an example embodiment.

In this specification, “front” denotes the direction from the back plate 630 to the cover window 620, and the opposite direction is referred to as “rear.”

The display device according to an example embodiment may, for example, be used in a state of being fixedly coupled to another object. The display device according to an example embodiment may be, for example, a vehicle display device mounted in front of the driver's seat in a vehicle.

As shown in FIGS. 2 and 3, the display device may be used in a state of being coupled to an object and maintained in an upright position.

Accordingly, since the display device is used in a state of being fixedly coupled to the object, its upper and lower sides may be distinguished.

As illustrated in FIG. 3, in this specification, “upward direction” denotes a direction from the first circuit board 310 toward the second circuit board 320, and the opposite direction is referred to as “downward direction.” The terms “upper” and “lower” as used in this specification may be interpreted accordingly.

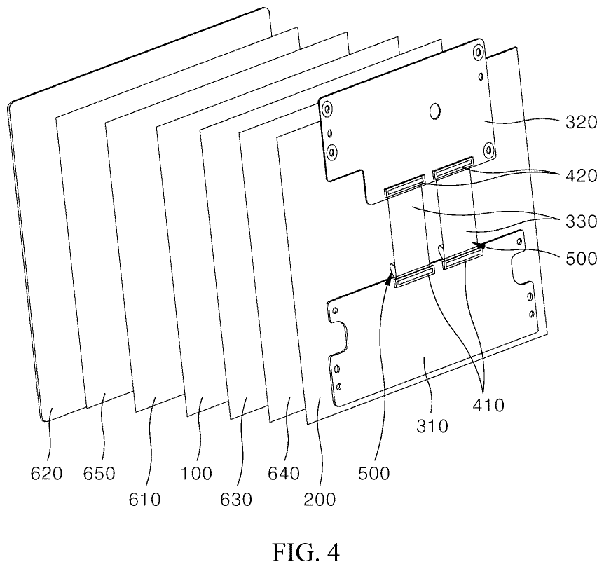

FIG. 4 is an exploded perspective view of a display device according to an example embodiment. Hereinafter, the overall structure of the display device will first be described with reference to FIG. 4.

The display device may include a display panel 100, a metal plate 200, and a board unit 300.

The display panel 100 may display images or videos. In a vehicle display device, the displayed images may include navigation information for driving, video captured by cameras mounted in the vehicle, or various other content requested by the driver or passengers.

The metal plate 200 may be disposed behind the display panel 100 and the back plate 630. The metal plate 200 may be formed to have a thin shape for manufacturing a slim-type display device. The rear surface of the metal plate 200 may be exposed to the air, allowing for heat transfer to the atmosphere.

The metal plate 200 may protect the display panel 100 and the back plate 630 and may serve as a heat sink by dissipating heat generated from the display panel 100 and the back plate 630 to the outside to cool the display panel 100 and the back plate 630.

For effective heat dissipation, the metal plate 200 may be formed of a material with high thermal conductivity. The metal plate 200 may be made of, for example, aluminum or an alloy including aluminum.

The board unit 300 may be disposed behind the metal plate 200. The board unit 300 may include a device for supplying electricity to the display device and may implement a control unit for controlling the operation of the display device.

The circuit board may include various active elements, passive elements, circuits, and connectors for electrical connection to implement the control unit. The board unit 300 may include a first circuit board 310, a second circuit board 320, and a third circuit board 330.

The first circuit board 310 and the second circuit board 320 of the board unit 300 may be coupled to a coupling structure provided on the object to which the display device is mounted, for example, using a coupling mechanism such as screws. The third circuit board 330 may have both ends coupled to the first circuit board 310 and the second circuit board 320, respectively.

The first circuit board 310 may be disposed behind the metal plate 200 and may be positioned at the lower portion of the display device. The first circuit board 310 may, for example, connect the vehicle's main control module to the second circuit board 320 and supply electricity to the second circuit board 320.

Additionally, the first circuit board 310 may perform timing control for communication signals of the board unit 300. The first circuit board 310 may include various active components, passive components, and electrical circuits to perform these functions.

The second circuit board 320 may be disposed behind the metal plate 200 and positioned above the first circuit board 310. The second circuit board 320 may be electrically connected to the first circuit board 310 through the third circuit board 330. The second circuit board 320 may control various operations of the display device.

The second circuit board 320 may include devices for communication with external devices such as a camera or the vehicle's main control module, devices for driving the display panel 100 to display images or video, circuits, and various active and passive components.

The first circuit board 310 and the second circuit board 320 may be provided as rigid circuit boards that are not deformed by external forces.

The third circuit board 330 may be disposed behind the metal plate 200 and electrically connect the first circuit board 310 and the second circuit board 320. The third circuit board 330 may be formed of a flexible material and serve as a cable for electrically connecting the first circuit board 310 and the second circuit board 320.

Since the third circuit board 330 is made of a flexible material, the positioning and configuration of the first circuit board 310 and the second circuit board 320 can be freely adjusted. The third circuit board 330 may include various active components, passive components, and electrical circuits to perform the aforementioned functions.

The display device according to an example embodiment may include a first connector 410 and a second connector 420. The first connector 410 may electrically connect the first circuit board 310 and the third circuit board 330.

The first connector 410 may be formed to slightly protrude from the rear surface of the first circuit board 310 and may have pins for electrical coupling with the third circuit board 330. These pins may be provided in plurality and aligned with slight gaps therebetween.

Meanwhile, the first connector 410 may be provided in a plurality, and each of the plurality of connectors may be coupled to the third circuit board 330. Therefore, the third circuit board 330 may be provided in plurality, corresponding to the number of first connectors 410.

The second connector 420 may be coupled to the second circuit board 320 and electrically connect the second circuit board 320 with the third circuit board 330. The structure of the second connector 420 may be similar to that of the first connector 410.

The second connector 420 may be formed to slightly protrude from the rear surface of the second circuit board 320 and may have pins for electrical coupling with the third circuit board 330. These pins may be provided in plurality and aligned with slight gaps therebetween.

Meanwhile, the second connector 420 may be provided in plurality, and each of the plurality of connectors may be coupled to the third circuit board 330.

According to an example embodiment, the display device may include a polarizing plate 610, a cover window 620, and a back plate 630.

The polarizing plate 610 may be disposed in front of the display panel 100 and behind the cover window 620. The polarizing plate 610 may convert light emitted from the display panel 100 into circularly polarized light. The polarizing plate 610 may improve outdoor visibility and contrast ratio of an image displayed on the display panel 100 by reducing or preventing reflection of external light.

The cover window 620 may be disposed in front of the polarization plate 610 and at the very front of the display device, forming the exterior appearance of the display device.

The cover window 620 may be positioned in front of the display panel 100 to protect the display panel 100. The cover window 620 may be formed of a transparent material such that light emitted from the display panel 100 may pass through the cover window 620.

The cover window 620 may be made of transparent glass or transparent plastic, but is not limited to these materials.

The cover window 620 may be formed relatively thick to protect the components behind it and maintain the rigidity of the entire display device, reducing or preventing it from easily deforming due to external impacts.

The back plate 630 may be disposed behind the display panel 100 and in front of the metal plate 200. The back plate 630 may support the thin display panel 100, reinforcing the rigidity of the display panel 100 and reducing or preventing deformation of the display panel 100.

According to an example embodiment, the back plate 630 may include a light source that irradiates light to the display panel 100.

The display device may include adhesive layers for bonding the respective components. According to an example embodiment, the display device may include a first adhesive layer 640 and a second adhesive layer 650. However, the present disclosure is not limited thereto, and the number of adhesive layers may be three or more as needed.

The first adhesive layer 640 may be disposed between the back plate 630 and the metal plate 200, and may bond the back plate 630 and the metal plate 200 to each other. The second adhesive layer 650 may be disposed between the polarizing plate 610 and the cover window 620, and may bond the polarizing plate 610 and the cover window 620 to each other.

The first adhesive layer 640 and the second adhesive layer 650 may be provided in a film or sheet form and may be formed of an adhesive material. In particular, since light emitted from the display panel 100 is typically pass through the second adhesive layer 650, the second adhesive layer 650 may be formed of a transparent material having high light transmittance.

For example, the first adhesive layer 640 and the second adhesive layer 650 may be formed of or include a material having strong adhesion, such as an optical clear adhesive (OCA), optical clear resin (OCR), or pressure sensitive adhesive (PSA).

In particular, the second adhesive layer 650 may be formed of or include an OCA or OCR, which are transparent materials having high light transmittance.

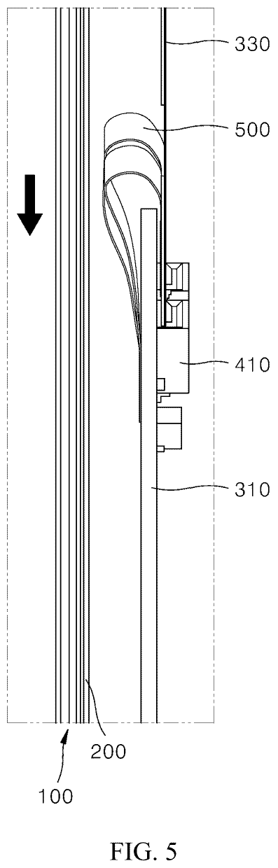

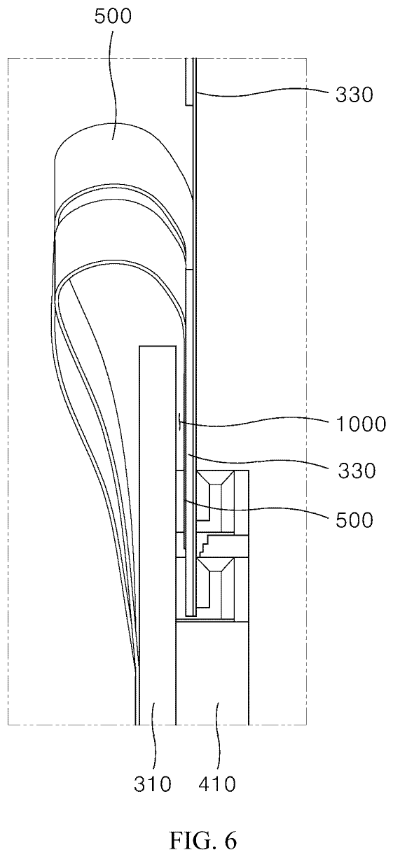

FIG. 5 is a partial side view of a display device according to an example embodiment. The arrow shown in FIG. 5 indicates the direction of gravity. FIG. 6 is an enlarged view of a portion of FIG. 5.

As shown in FIGS. 3 and 5, when the display device is assembled for regular use, it may be oriented in a direction parallel to gravity when viewed from the side.

In this case, the first circuit board 310 may be disposed at a lower portion of the display device, and the second circuit board 320 may be disposed at an upper portion of the display device. Accordingly, the first circuit board 310 and the second circuit board 320 may be disposed on the lower side and the upper side, respectively, in a direction parallel to the direction of gravity.

The third circuit board 330 may be arranged with its length direction aligned with the vertical direction of the display device. Here, when the third circuit board 330 is coupled to the first connector 410 protruding from the rear surface of the first circuit board 310, a separation space 1000 may be formed between the first circuit board 310 and the third circuit board 330.

This is because the third circuit board 330 is not adhered to a surface of the first circuit board 310, but rather coupled to the first connector 410 protruding from the first circuit board 310 while being spaced apart from the surface of the first circuit board 310 to some extent. Due to this structure, the aforementioned separation space 1000 may be formed between the first circuit board 310 and the third circuit board 330.

The separation space 1000 may be defined with an open -upper side and a lower side closed by the first connector 410. Foreign substances such as dust or metal particles floating in the air may fall in the direction of gravity.

Accordingly, such foreign substances may fall and enter the separation space 1000 having an open upper side, and may accumulate therein. When foreign substances are introduced and accumulate in the separation space 1000, they may cause issues such as disconnection in the electrical connection structure.

Particularly, when the display device is continuously used, foreign substances may continuously ingress into the separation space 1000, potentially causing malfunction or failure of the display device, and in extreme cases, combustible foreign substances may cause a fire in the display device.

Foreign substances from the external environment descend due to gravity, and such gravity-driven substances may easily enter the separation space 1000, which is open in the direction parallel to gravity. As described above, foreign substances that continuously enter and accumulate in the separation space 1000 may adversely affect the display device.

In particular, when metallic particles enter the separation space 1000, the high-density particles may readily fall into the space due to gravity, and since such particles are conductive foreign substances, their presence and movement may pose a significant risk of causing operational failure or damage to the display device. Accordingly, such metallic particles should be prevented or suppressed from being introduced into the separation space 1000.

Therefore, a structure capable of suppressing the ingress of foreign substances into the separation space 1000 should be provided.

Meanwhile, a similar separation region to the previously mentioned separation space 1000 may be formed in the structure where the second circuit board 320, the second connector 420, and the third circuit board 330 are coupled. However, in this case, the upper side of the separation region is closed by the second connector 420, and the lower side is open.

Therefore, foreign substances falling due to gravity are less likely to accumulate in the separation region, as the bottom is open. Thus, the accumulation of foreign substances in the separation region formed by the coupling of the second circuit board 320, the second connector 420, and the third circuit board 330 may not be a concern.

Therefore, the following will provide a more detailed description of a structure that reduces or prevents foreign substances from accumulating in the separation space 1000 formed by the coupling of the first circuit board 310, the first connector 410, and the third circuit board 330.

According to an example embodiment, the display device may include a guard member 500. The guard member 500 may be coupled to the first circuit board 310 and the third circuit board 330, with a portion disposed above the separation space 1000 formed between the first circuit board 310 and the third circuit board 330.

The number of the guard member(s) 500 may be provided correspondingly to the number of the first circuit board(s) 310 and the third circuit board(s) 330 that are connected with each other. As the drawings in this specification show two combinations of the first circuit board 310 and third circuit board 330 that are connected with each other, two guard members 500 may be provided. Of course, when there are three or more combinations of the first circuit board 310 and the third circuit board 330 that are connected with each other, the guard member 500 may also be provided as three or more.

The guard member 500 may be disposed above the separation space 1000, which has an open upper side and a closed lower side. This structure allows the guard member 500 to effectively reduce or prevent foreign substances, such as dust and metallic particles falling due to gravity from the upper portion of the display device, from entering the separation space 1000.

Thus, the guard member 500 may suppress the ingress of foreign substances into the separation space 1000, effectively reducing or preventing operational failures or damage to the display device caused by the accumulation of such substances, and thereby improving the durability of the display device.

The guard member 500 may be formed as a thin film, which may be in an unbent state during manufacturing. However, when the display device is assembled, the guard member 500 may be bent and disposed above the separation space 1000, thereby blocking the ingress of foreign substances falling due to gravity through the open upper side of the separation space 1000.

The guard member 500 may be formed as a thin film, with at least a portion bent into a curved shape, and disposed above the separation space 1000.

For example, as shown in FIG. 5, the bent portion of the guard member 500 may be disposed in the space formed between the metal plate 200 and the third circuit board 330, which face each other. That is, at least a portion of the guard member 500 may be disposed between the third circuit board 330 and the metal plate 200.

Meanwhile, the bent structure of the guard member 500 does not need to be uniformly consistent in the lateral direction of the first circuit board 310. That is, the bent structure of the guard member 500 may be disposed with some inclination when viewed in the lateral direction of the first circuit board 310.

Due to this inclined arrangement, as shown in FIG. 5, when viewed from the side, the bent portion of the guard member 500 may appear to have varying widths at different points.

The guard member 500 may be manufactured without a bent portion and have a portion bent during the assembly of the display device. For example, a rigid guard member 500, which is difficult to deform under external force, may be heated during the bending process to become somewhat flexible and bent under external force.

Afterward, the guard member 500 cools down and returns to its rigid material state, thus maintaining its designed position stably and effectively reducing or preventing foreign substance ingress into the separation space 1000.

Therefore, the guard member 500 may be made of a plastic material that meets this assembly process. For example, the guard member 500 may be made of fiberglass-reinforced epoxy (FR4), polyethylene terephthalate (PET), or polyimide, which have suitable material properties.

In particular, fiberglass-reinforced epoxy is a suitable material for the guard member 500 in the example embodiment due to its electrical insulation, flame resistance, high heat resistance, and mechanical strength.

The guard member 500 needs to continuously maintain at least part of its structure positioned above the separation space 1000. Therefore, the guard member 500 must be securely attached to other components of the display device.

To achieve this, in an example embodiment, one end of the guard member 500 may be adhered to one surface of the third circuit board 330, and the other end may be adhered to one surface of the first circuit board 310. This structure can be realized by bending part of the guard member 500.

Specifically, the guard member 500 may be bent from the part adhered to one surface of the third circuit board 330, and its end may extend over the upper side of the first circuit board 310 and adhere to one surface of the first circuit board 310.

As illustrated in FIG. 6, one end of the guard member 500 may be adhered to a surface of the third circuit board 330 facing the first circuit board 310, and the other end may be adhered to a surface of the first circuit board 310, which is opposite to the surface facing the third circuit board 330.

This structure allows the upper side of separation space 1000, formed between the facing surfaces of first circuit board 310 and third circuit board 330, to be completely enclosed by the bent portion of guard member 500.

As a result, foreign substances descending due to gravity cannot access the open upper side of separation space 1000, significantly and effectively suppressing their entry and accumulation in separation space 1000.

In an example embodiment, the first connector 410 may be coupled to first circuit board 310 to protrude from one surface thereof. Additionally, third circuit board 330 may be coupled to the connector to be spaced apart from first circuit board 310.

Consequently, a separation space 1000 with an open upper side and a lower side closed by first connector 410 may be formed between third circuit board 330 and first circuit board 310. Of course, it may be possible to reduce the size of the separation space 1000 to some extent by modifying the structures of the first circuit board 310, the third circuit board 330, and the first connector 410; however, it is difficult to completely eliminate the separation space 1000, and thus, the separation space 1000 may still exist.

Therefore, a structure for suppressing the ingress of foreign substances into the separation space 1000 should be provided, and in an example embodiment, this need is addressed by disposing a portion of the guard member 500 above the separation space 1000.

In other words, guard member 500 is disposed to cover separation space 1000 above the space formed between first circuit board 310 and third circuit board 330, suppressing the entry of foreign substances descending due to gravity into separation space 1000.

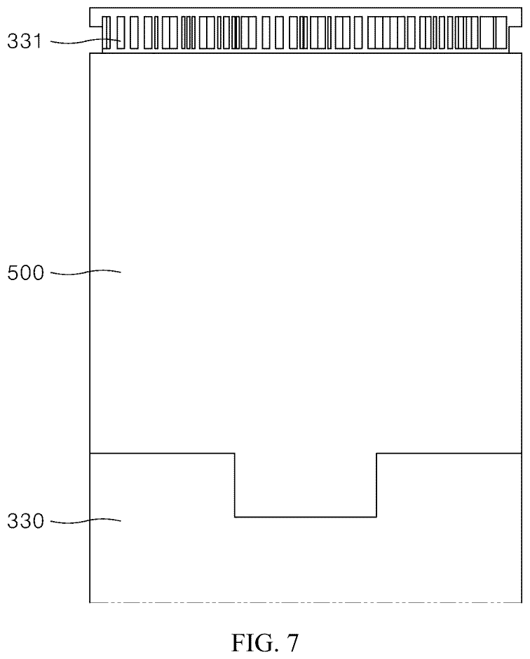

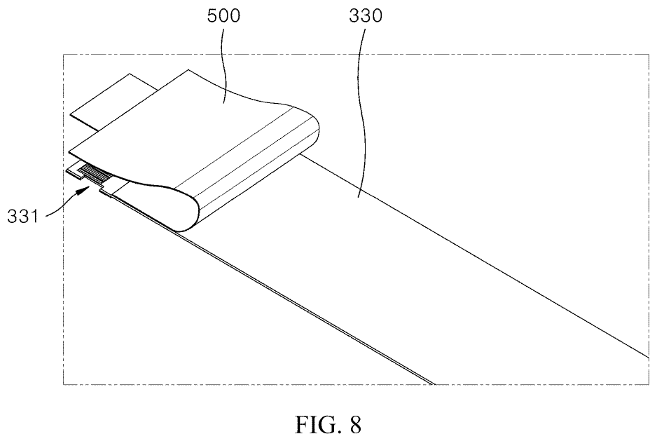

FIG. 7 is a view illustrating the third circuit board 330 and the guard member 500 according to an example embodiment. FIG. 8 is a perspective view illustrating the guard member 500 in a bent state from FIG. 7.

Third circuit board 330 may have connection pins 331 formed for electrical connection with pins on first connector 410. The connection pins 331 may be provided in a shape and number corresponding to the pins of the first connector 410.

A portion of the guard member 500 that is not bent may be adhered to a surface of the first circuit board 310. In an example embodiment, the adhered portion of the guard member 500 may include an avoidance area to bypass the connection pins 331 while being adhered to one surface of the first circuit board 310. The assembly process of the guard member 500 in the display device is as follows.

First, as shown in FIG. 7, the guard member 500 in a flat, unbent state may be adhered to a surface of the third circuit board 330. Here, one end of the guard member 500, excluding the portion to be bent, may be adhered to the surface of the third circuit board 330.

Next, as shown in FIG. 8, during the assembly process of the display device, the guard member 500 may be heated to become somewhat flexible, and a portion of the guard member 500 may be bent using a bending device or by an operator.

Then, the other end of the guard member 500 may be adhered to the surface of the first circuit board 310. When the guard member 500 is adhered to the first circuit board 310, the open upper side of the separation space 1000 formed between the first circuit board 310 and the third circuit board 330 may be enclosed by the guard member 500.

In an example embodiment, the guard member 500 may be fabricated in a flat state and easily bent during the assembly process of the display device to be mounted to the display device. This structure may effectively suppress the entry of foreign substances into the separation space 1000 without introducing complex structures or processes to the display device. Thus, the display device can be significantly improved while reducing manufacturing costs.

According to an example embodiment, a display device may include a display panel, a metal plate disposed behind the display panel, a first circuit board disposed behind the metal plate, a second circuit board disposed behind the metal plate and above the first circuit board, a third circuit board disposed behind the metal plate and configured to electrically connect the first circuit board and the second circuit board, a first connector configured to electrically connect the first circuit board and the third circuit board, and a guard member coupled to the first circuit board and the third circuit board, with a portion disposed above a separation space formed between the first circuit board and the third circuit board.

The guard member may have one end adhered to a surface of the third circuit board and another end adhered to a surface of the first circuit board.

The guard member may be formed as a thin film, with at least a portion bent in a curved shape and disposed above the separation space.

The guard member may be formed of glass fiber-reinforced epoxy (FR4), polyethylene terephthalate (PET), or polyimide material.

The guard member may be bent from a portion adhered to a surface of the third circuit board, extend over an end of the first circuit board from above, and be adhered to a surface of the first circuit board.

The guard member may have one end adhered to a surface of the third circuit board facing the first circuit board and another end adhered to a surface of the first circuit board opposite the surface facing the third circuit board.

The first connector may be coupled to the first circuit board to protrude from a surface thereof, and the third circuit board may be coupled to the first connector to be spaced apart from the first circuit board.

The guard member may be disposed to cover the separation space above the space formed between the first circuit board and the third circuit board, and may be configured to block foreign substances from entering the separation space.

According to an example embodiment, the display may further include a second connector coupled to the second circuit board and configured to electrically connect the second circuit board and the third circuit board.

According to an example embodiment, the display device may further include a polarizing plate disposed in front of the display panel, a cover window disposed in front of the polarizing plate, and a backplate disposed behind the display panel and in front of the metal plate.

According to an example embodiment, the display device may further include a first adhesive layer disposed between the backplate and the metal plate, and a second adhesive layer disposed between the polarizing plate and the cover window.

According to an example embodiment, a display device may include a metal plate, a first circuit board disposed behind the metal plate, a second circuit board disposed behind the metal plate and above the first circuit board, a third circuit board disposed behind the metal plate and configured to electrically connect the first circuit board and the second circuit board, a first connector configured to electrically connect the first circuit board and the third circuit board, and a guard member coupled to the first circuit board and the third circuit board and disposed to cover a separation space above the space formed between the first circuit board and the third circuit board.

According to an example embodiment, the display device may further include a display panel disposed in front of the metal plate, a polarizing plate disposed in front of the display panel, a cover window disposed in front of the polarizing plate, and a backplate disposed behind the display panel and in front of the metal plate.

According to an example embodiment, the display device may further include a first adhesive layer disposed between the backplate and the metal plate, and a second adhesive layer disposed between the polarizing plate and the cover window.

The guard member may have one end adhered to a surface of the third circuit board and another end adhered to a surface of the first circuit board.

The guard member may be formed as a thin film, with at least a portion bent into a curved shape and disposed above the separation space, bent from a portion adhered to a surface of the third circuit board, extending over an end of the first circuit board from above, and adhered to a surface of the first circuit board.

The guard member may have one end adhered to a surface of the third circuit board facing the first circuit board and another end adhered to a surface of the first circuit board opposite the surface facing the third circuit board.

The first connector may be coupled to the first circuit board to protrude from a surface thereof, and the third circuit board may be coupled to the first connector to be spaced apart from the first circuit board.

The separation space may have an open upper side and a lower side closed by the first connector.

While the present disclosure has been described above with reference to example drawings, it is not limited to the example embodiments and drawings disclosed in this specification, and it will be apparent to those skilled in the art that various modifications may be made without departing from the scope of the technical idea of the disclosure. Furthermore, even if the operational effects according to various configurations of the present disclosure are not explicitly described in the explanation of the example embodiments, the predictable effects resulting from the corresponding configurations should naturally be recognized as well.

What is claimed is:

1. A display device, comprising:
a display panel;
a metal plate disposed behind the display panel;
a first circuit board disposed behind the metal plate;
a second circuit board disposed behind the metal plate and above the first circuit board;
a third circuit board disposed behind the metal plate and configured to electrically connect the first circuit board and the second circuit board;
a first connector configured to electrically connect the first circuit board and the third circuit board; and
a guard member coupled to the first circuit board and the third circuit board, with a portion disposed above a separation space formed between the first circuit board and the third circuit board.

2. The display device of claim 1, wherein the guard member has one end adhered to a surface of the third circuit board and another end adhered to a surface of the first circuit board.

3. The display device of claim 1, wherein the guard member is formed as a thin film, with at least a portion bent in a curved shape and disposed above the separation space.

4. The display device of claim 1, wherein the guard member is formed of glass fiber-reinforced epoxy (FR4), polyethylene terephthalate (PET), or polyimide material.

5. The display device of claim 3, wherein the guard member is bent from a portion adhered to a surface of the third circuit board, extends over an end of the first circuit board from above, and is adhered to a surface of the first circuit board.

6. The display device of claim 1, wherein the guard member has one end adhered to a surface of the third circuit board facing the first circuit board and another end adhered to a surface of the first circuit board opposite the surface facing the third circuit board.

7. The display device of claim 1, wherein:
the first connector is coupled to the first circuit board to protrude from a surface of the first circuit board; and
the third circuit board is coupled to the first connector to be spaced apart from the first circuit board.

8. The display device of claim 7, wherein the guard member is disposed to cover the separation space above a space formed between the first circuit board and the third circuit board, and is configured to block foreign substances from entering the separation space.

9. The display device of claim 1, further comprising a second connector coupled to the second circuit board and configured to electrically connect the second circuit board and the third circuit board.

10. The display device of claim 1, further comprising:
a polarizing plate disposed in front of the display panel;
a cover window disposed in front of the polarizing plate; and
a backplate disposed behind the display panel and in front of the metal plate.

11. The display device of claim 10, further comprising:
a first adhesive layer disposed between the backplate and the metal plate; and
a second adhesive layer disposed between the polarizing plate and the cover window.

12. A display device, comprising:
a metal plate;
a first circuit board disposed behind the metal plate;
a second circuit board disposed behind the metal plate and above the first circuit board;
a third circuit board disposed behind the metal plate and configured to electrically connect the first circuit board and the second circuit board;
a first connector configured to electrically connect the first circuit board and the third circuit board; and
a guard member coupled to the first circuit board and the third circuit board and disposed to cover a separation space above a space formed between the first circuit board and the third circuit board.

13. The display device of claim 12, further comprising:
a display panel disposed in front of the metal plate;
a polarizing plate disposed in front of the display panel;
a cover window disposed in front of the polarizing plate; and
a backplate disposed behind the display panel and in front of the metal plate.

14. The display device of claim 13, further comprising:
a first adhesive layer disposed between the backplate and the metal plate; and
a second adhesive layer disposed between the polarizing plate and the cover window.

15. The display device of claim 12, wherein the guard member has one end adhered to a surface of the third circuit board and another end adhered to a surface of the first circuit board.

16. The display device of claim 12, wherein:
the guard member is formed as a thin film, with at least a portion bent in a curved shape and disposed above the separation space; and
the guard member is bent from a portion adhered to a surface of the third circuit board, extends over an end of the first circuit board from above, and is adhered to a surface of the first circuit board.

17. The display device of claim 12, wherein the guard member has one end adhered to a surface of the third circuit board facing the first circuit board and another end adhered to a surface of the first circuit board opposite the surface facing the third circuit board.

18. The display device of claim 12, wherein:
the first connector is coupled to the first circuit board to protrude from a surface of the first circuit board; and
the third circuit board is coupled to the first connector to be spaced apart from the first circuit board.

19. The display device of claim 12, wherein the separation space has an open upper side and a lower side closed by the first connector.
